(19) United States
(12) Patent Application Publication
(10) Pub. No.: US 2025/0218966 A1
(43) Pub. Date: Jul. 3, 2025

(54) SUBSTRATE HAVING ASYMMETRIC METALLIZATION STRUCTURES DISPOSED ON OPPOSITE SIDES OF A CENTRAL CORE

(71) Applicant: QUALCOMM Incorporated, San Diego, CA (US)

(72) Inventors: Manuel ALDRETE, Encinitas, CA (US); Aniket PATIL, San Diego, CA (US); Joan Rey Villarba BUOT, Escondido, CA (US)

(21) Appl. No.: 18/399,435

(22) Filed: Dec. 28, 2023

(51) Int. Cl. H01L 23/538; H01L 21/48; H01L 23/64

(52) U.S. Cl. CPC H01L 23/5386; H01L 21/4857; H01L 23/5383; H01L 23/642

(57) ABSTRACT

In an aspect, a substrate includes a core having a first surface and a second surface opposite the first surface; a first set of metallization layers disposed over the first surface; an offset layer structure disposed over the second surface; and a second set of metallization layers disposed over the second surface, wherein the second set of metallization layers includes a larger number of metallization layers than the first set of metallization layers.

### FIELD OF DISCLOSURE

The present disclosure generally relates to a substrate, and more particularly, to a substrate having asymmetric metallization structures disposed on opposite sides of a central core, and methods of making the substrate.

### BACKGROUND

Integrated circuit (IC) technology has achieved great strides in advancing computing power through miniaturization of electrical components. An IC may be implemented as an IC chip with a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-a-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

Some substrates employ a central core material, usually a rigid and thermally stable dielectric, sandwiched between conductive material layers, such as copper. This central core provides structural rigidity and supports the substrate's thermal and electrical performance requirements. Such substrates are fabricated by forming metallization layers on the central core that are built up during the fabrication process.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a substrate includes a core having a first surface and a second surface opposite the first surface; a first set of metallization layers disposed over the first surface; an offset layer structure disposed over the second surface; and a second set of metallization layers disposed over the second surface, wherein the second set of metallization layers includes a larger number of metallization layers than the first set of metallization layers.

In an aspect, an electronic device includes a substrate comprising: a core having a first surface and a second surface opposite the first surface; a first set of metallization layers disposed over the first surface; an offset layer structure disposed over the second surface; and a second set of metallization layers disposed over the second surface, wherein the second set of metallization layers includes a larger number of metallization layers than the first set of metallization layers.

In an aspect, a method of fabricating a substrate includes forming a first set of metallization layers over a first surface of a core, wherein the core includes a second surface opposite the first surface; forming an offset layer structure over the second surface; and forming a second set of metallization layers over the second surface, wherein the first set of metallization layers includes a larger number of metallization layers than the second set of metallization layers.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 is a cross-sectional view of an example of a symmetric substrate, according to aspects of the disclosure.

FIG. 2 is a cross-sectional view of an example asymmetric substrate, according to aspects of the disclosure.

FIG. 3A through FIG. 3D show example processing operations that may be undertaken to embed an electronic component in a central core of a substrate, according to aspects of the disclosure.

FIG. 4A through FIG. 4I show example processing operations for fabricating an asymmetric substrate, according to aspects of the disclosure.

FIG. 5 is a flowchart showing an example method for fabricating a substrate, according to aspects of the disclosure.

FIG. 6 illustrates a profile view of a package that includes a surface mount substrate, an integrated device, and an integrated passive device (e.g.,

FIG. 7 illustrates an example method for providing or fabricating a package that includes an integrated device comprising an electronic component mounted in a core, according to aspects of the disclosure.

FIG. 8 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (POP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Certain aspects of the disclosure are directed to substrates formed from a central core. Such central cores usually include a rigid and thermally stable dielectric material, which is sandwiched between layers of conductive material, such as copper. Metallization structures formed from metallization layers and corresponding dielectric layers are built up on opposite sides of the central core during the substrate fabrication process. Substrates fabricated using conventional fabrication processes are formed as symmetric substrate structures in that the same number of metallization layers and corresponding dielectric layers are built up on opposite sides of the central core.

Certain aspects of the disclosure are implemented with a recognition that symmetric substrate structures are not necessarily optimal for use in certain electronic packaging scenarios. Accordingly, certain aspects of the disclosure are directed to an asymmetric substrate structure in which the metallization structures disposed over opposite sides of the central core are formed from differing numbers of metallization and dielectric layers. In accordance with certain aspects of the disclosure, an offset layer structure is disposed over the side of the central core over which the larger number of metallization and dielectric layers are formed.

In an aspect, the offset layer structure may include one or more pre-preg (PPG) layers, where each PPG layer comprises a fabric that has been impregnated with a resin. In an aspect, the PPG layer may be applied over the central core prior to curing of the resin, which is subsequently cured during another processing operation of the substrate fabrication process.

Certain aspects of the disclosure are implemented with a recognition that symmetric substrate structures may not be optimal for use in electronic packaging scenarios in which an electronic component, such as a deep trench capacitor, is embedded in the central core. Symmetric substrate structures typically do not have the desired degree of control over the spacing between the embedded electronic component and the outer surfaces of the symmetric substrate to which other electronic components (e.g., integrated circuits (ICs), passive components, discrete act of components, etc.) are coupled to the substrate.

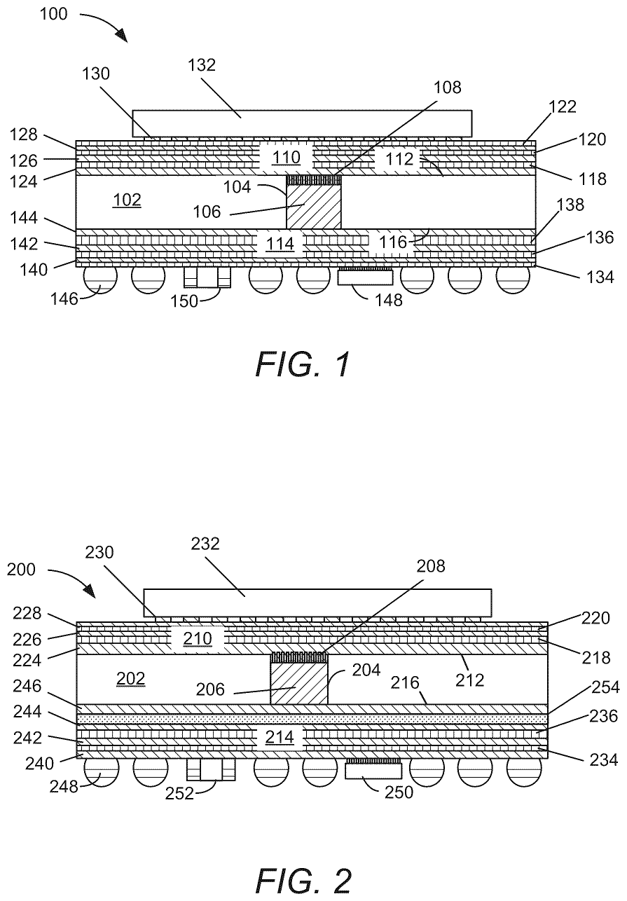

FIG. 1 is a cross-sectional view of an example of a symmetric substrate 100, according to aspects of the disclosure. In this example, the substrate 100 includes a central core 102 having a cavity 104 that extends through the central core 102. An electronic component 106 is disposed within the cavity 104. The electronic component 106 has an upper surface with metal terminals 108 that provide an electrical connection to the electronic component 106. In accordance with various aspects of the disclosure, the electronic component 106 may be one or more of an active electronic component, a passive electronic component (e.g., a deep trench capacitor (DTC)), a die, etc.

In accordance with various aspects of the disclosure, the substrates described herein that include a core and an embedded electronic component are directed to package substrates. A package substrate is the part of an integrated circuit package that gives the board its mechanical strength and allows it to connect with external devices. Such package substrates are to be distinguished from other substrates, such as the substrates that may be included in the embedded electronic component itself, dies including substrates (e.g., silicon substrates or other similar electronic devices).

The substrate 100 further includes a first metallization structure 110 disposed over a first surface 112 of the central core 102 and a second metallization structure 114 disposed over a second surface 116 that is opposite the first surface 112 (e.g., the second surface 116 is on the opposite side of the central core 102 and typically parallel to the first surface 112). It will be recognized, based on the teachings of the present disclosure, that the particular patterning of the layers of the first metallization structure, the second metallization structure, as well as any vias interconnecting the metallization layers have been omitted for simplicity.

In this example, the first metallization structure 110 includes a plurality of dielectric layers 118, 120, and 122 and corresponding patterned metallization layers 124, 126, and 128 overlying the first surface 112 of the central core 102. The patterned metallization layer 124 disposed at the first surface 112 of the central core 102 may be configured to electrically couple the metal terminals 108 of the electronic component 106 with the first metallization structure 110. The patterned metallization layer 128 may configured to electrically couple the terminals 130 of a die 132 with the first metallization structure 110.

In this example, the second metallization structure 114 includes a plurality of dielectric layers 134, 136, and 138 and corresponding patterned metallization layers 140, 142, and 144 disposed over the second surface 116 of the central core 102. In an aspect, a patterned metallization layer 140 may be configured to electrically couple the second metallization structure 114 with a printed circuit board or other electronic packaging component through, for example, solder joints 146. In an aspect, the patterned metallization layer 140 may be configured to couple the second metallization structure 114 with other electronic components, such as a die 148 (e.g., a deep trench capacitor, an IC, etc.) and/or discrete electronic components 150 (e.g., resistors, capacitors, inductors, transistors, etc.).

Although the structure of the symmetric substrate 100 shown in FIG. 1 has been suitable for use in many high-performance applications (e.g., compute and automotive applications), such symmetric substrates may not be optimal for certain electronic packaging scenarios, particularly scenarios in which an electronic component (e.g., electronic component 106) is embedded in a central core (e.g., central core 102). Certain aspects of the disclosure are implemented with a recognition that it may be desirable to reduce the number of layers used for the first metallization structure 110 associated with coupling the embedded component with an electronic component at an outer surface of the symmetric substrate when compared to the number of layers used for the second metallization structure 114. As an example, when the embedded component (e.g., electronic component 106) is a deep trench capacitor that is electrically coupled to an IC (e.g., die 132) used in the implementation of a power distribution network (PDN), the number of layers forming the first metallization structure 110 between the first surface 112 of the central core 102 at which the electronic component 106 is connected and the die 132 (e.g., an IC used to implement the PDN) may influence the performance of the PDN. In certain scenarios, a larger number of layers may be undesirable due to the amount of parasitic capacitance introduced by the large number of layers of the first metallization structure 110 coupling the electronic component 106 with the die 132.

In contrast, electronic circuitry (e.g., logic circuitry such as die 148 mounted on the symmetric substrate and/or connected through the printed circuit board) may require higher density interconnects (and larger number of layers) for the second metallization structure 114. Since the symmetric substrate 100 employs the same number of layers for both the first metallization structure 110 and the second metallization structure 114, the number of layers associated with the second metallization structure 114 (e.g., the higher density interconnect structure) places a lower limit on the number of layers that may be used for the first metallization structure 110. Accordingly, the number of layers between the electronic component 106 (e.g., deep trench capacitor) and the die 132 (e.g., IC used to implement the PDN) may necessarily be larger than optimally desired. Similarly, if the number of layers associated with the first metallization structure 110 were to be optimized, the number of layers available to fabricate the second metallization structure 114 may be insufficient to accommodate any required high-density interconnections. In such instances, the

Certain aspects of the disclosure are implemented with a recognition that the deficiencies associated with the use of symmetric substrate structures may be addressed by using asymmetric substrate structures. For example, an asymmetric substrate structure with metallization structures having differing numbers of layers disposed at opposite surfaces of the central core may allow independent control of the number of layers used to couple an embedded component with a die at the surface of the asymmetric substrate.

FIG. 2 is a cross-sectional view of an example asymmetric substrate 200, according to aspects of the disclosure. In this example, the asymmetric substrate 200 includes a central core 202 having a cavity 204 that extends through the central core 202. An electronic component 206 is disposed within the cavity 204. The electronic component 206 has an upper surface with metal terminals 208 that provide an electrical connection to the electronic component 206. In accordance with various aspects of the disclosure, the electronic component 206 may be one or more of an active electronic component, a passive electronic component (e.g., a deep trench capacitor (DTC)), a die, etc.

The asymmetric substrate 200 further includes a first metallization structure 210 disposed over a first surface 212 of the central core 202 and a second metallization structure 214 disposed over a second surface 216 that is opposite the first surface 212. It will be recognized, based on the teachings of the present disclosure, that the particular patterning of the layers of the first metallization structure, the second metallization structure, as well as any vias interconnecting the metallization layers have been omitted for simplicity.

In this example, the first metallization structure 210 includes a plurality of dielectric layers 218, 220 and 254 and corresponding patterned metallization layers 224, 226, and 228 disposed over the first surface 212 of the central core 202. The patterned metallization layer 224 disposed at the first surface 212 of the central core 202 may be configured to electrically couple the metal terminals 208 of the electronic component 206 with the first metallization structure 210. The patterned metallization layer 228 may configured to electrically coupled the terminals 230 of a die 232 with the first metallization structure 210.

In this example, the second metallization structure 214 includes a plurality of dielectric layers 234, 236, and 243, and corresponding patterned metallization layers 240, 242, and 244 disposed over the second surface 216 of the central core 202. In an aspect, the patterned metallization layer 240 may be configured to electrically couple the second metallization structure 214 with a printed circuit board or other electronic packaging component through, for example, solder joints 248. In an aspect, the patterned metallization layer 240 may be configured to couple the second metallization structure 214 with other electronic components, such as a die 250 (e.g., a deep trench capacitor, an IC, etc.) and/or discrete electronic components 252 (e.g., resistors, capacitors, inductors, transistors, etc.).

The asymmetric substrate 200 shown in FIG. 2 also includes an offset layer structure 254 disposed over the second surface 216 of the central core 202. In this example, the offset layer structure 254 is disposed between the patterned metallization layers of the second metallization structure 214 (e.g., between patterned metallization layers 244 and 246). In an aspect, the offset layer structure 254 may have a thickness between 15 micrometers and 45 micrometers,

As shown in FIG. 2, the first metallization structure 210 includes three patterned metallization layers 224, 226, and 228, while the second metallization structure 214 includes four patterned metallization layers 240, 242, 244, and 246. In other words, the second metallization structure 214 includes more metallization layers than the first metallization structure 210. In an aspect, the number of metallization layers between the embedded electronic component 206 and the die 232 may be selected to reduce stray capacitances associated with the first metallization structure 210 and place the terminals 208 of the embedded electronic component 206 in closer proximity to the die 232. In contrast, the number of patterned metallization layers associated with the second metallization structure 214 may include all of the necessary metallization layers to ensure that there are enough conductive paths to carry signals and power to the solder joints 248, die 250, and/or discrete electronic component 252.

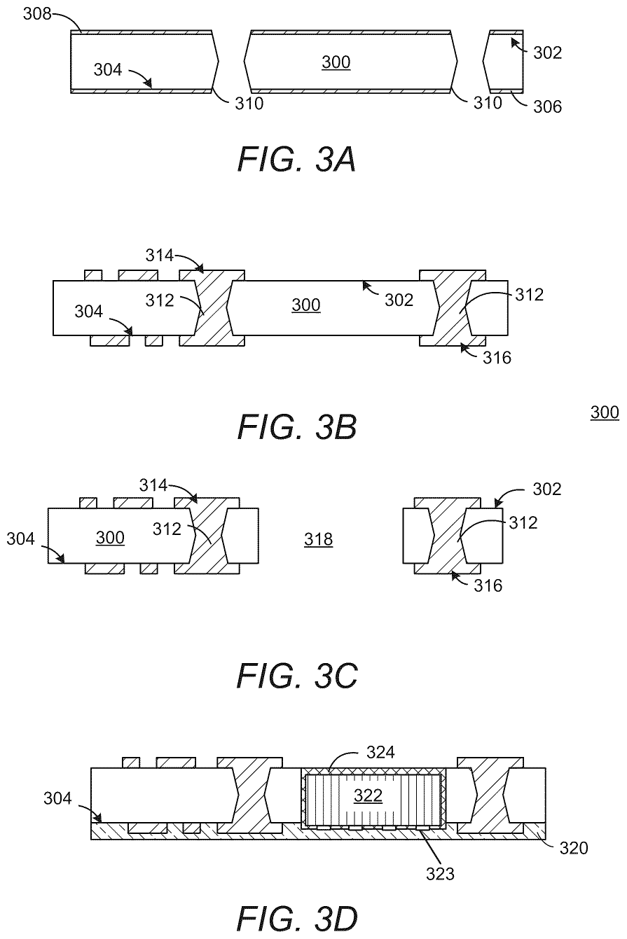

FIG. 3A through FIG. 3D show example processing operations that may be undertaken to embed an electronic component in a central core of a substrate, according to aspects of the disclosure. It will be understood, in view of the teachings of the disclosure, that many of the processing steps shown in FIG. 3A through FIG. 3D need not be undertaken in scenarios in which the asymmetric substrate does not include such an embedded electronic component.

FIG. 3A shows a central core 300 having a first surface 302 that is opposite a second surface 304. In its initial state, both the first surface 302 and the second surface 304 each include a corresponding metal layer 306 and 308 (e.g., metal cladding). In FIG. 3A, the central core 300 has been processed to fabricate via openings 310 extending through the central core 300.

In FIG. 3B, the via openings 310 shown in FIG. 3A have been filled to form vias 312 that couple a patterned metallization layer 314 disposed over the first surface 302 with a patterned metallization layer 316 disposed over the second surface 304. In an aspect, the patterned metallization layer 314 may be formed using a standard electroplating/masking/etching process that uses the metal layer 308 as a seed layer, and patterned metallization layer 316 may be formed using the standard electroplating/masking/etching process in which the metal layer 306 is used as the seed layer.

FIG. 3C and FIG. 3D show example processes that may be employed to embed an electronic component in the central core. In FIG. 3C, a cavity 318 is formed through the central core 300. In FIG. 3D, a polyimide (PI) tape 320 is disposed over the second surface 304 and covers the lower opening of the cavity 318. The electronic component 322 that is to be embedded is inserted into the cavity 318 so that the terminals 323 of the electronic component 322 are in contact with the PI tape 320. Once the electronic component 322 has been inserted, it may be secured within the cavity 318 by a dielectric material 324.

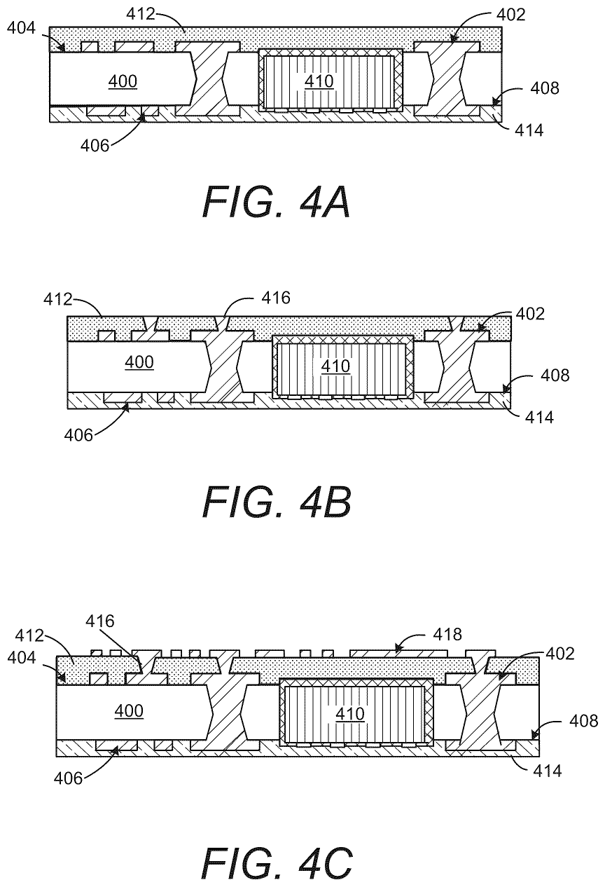

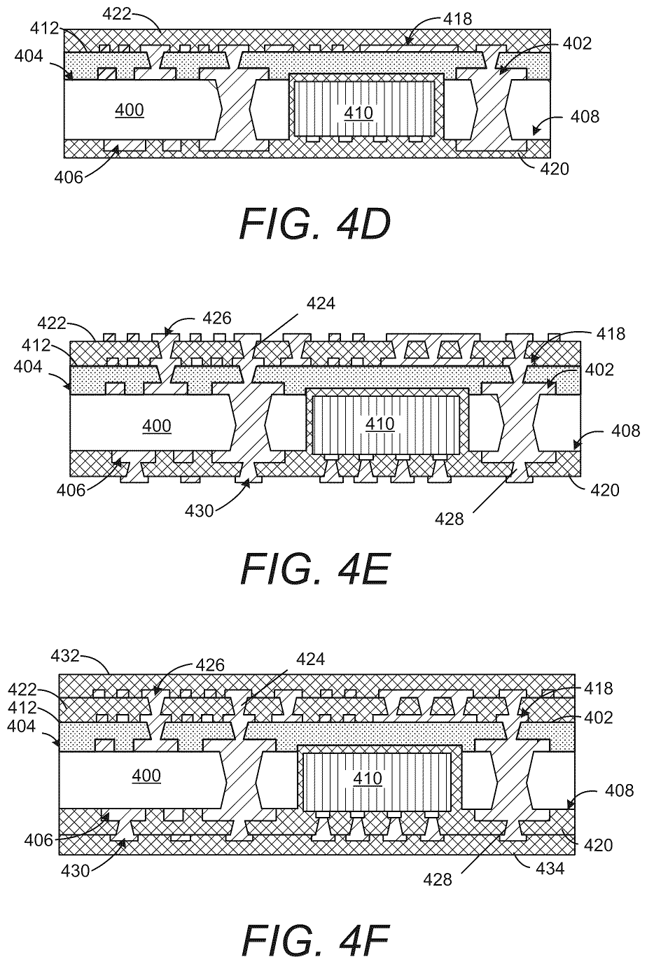

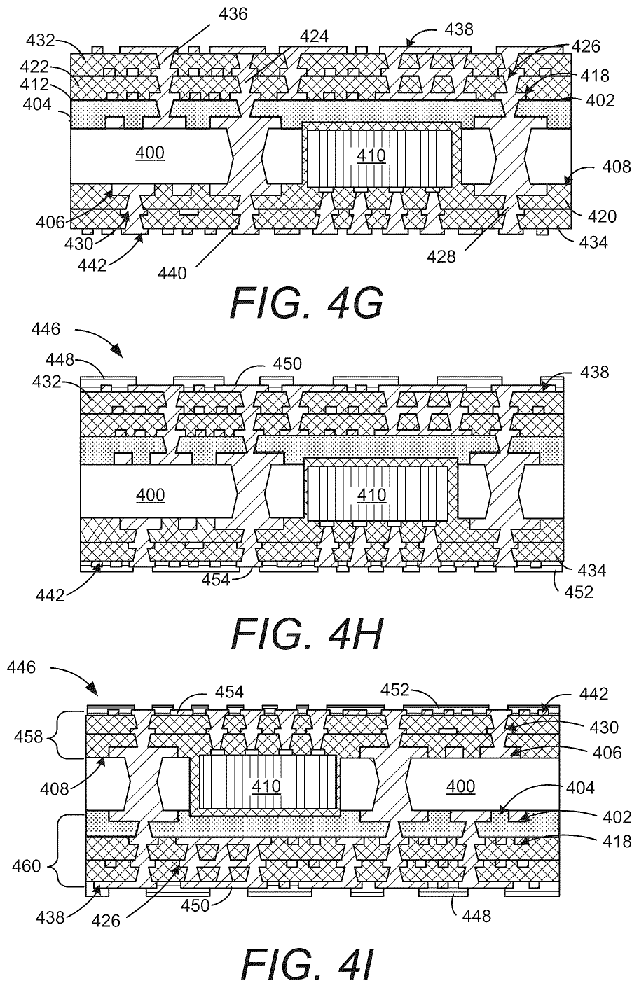

FIG. 4A through FIG. 4I show example processing operations for fabricating an asymmetric substrate, according to aspects of the disclosure. In this example, the processing operations are shown starting with an initial structure having a central core 400 that includes a patterned metallization layer 402 disposed over a first surface 404 of the central core 400 and another patterned metallization layer 406 disposed over a second surface 408 of the central core 400. Additionally, the initial structure in this example includes an electronic component 410 embedded in the central core 400. However, it will be recognized, based on the teachings of the present disclosure, that the initial structure need not have an embedded electronic component yet may still serve as an initial structure that may be used to fabricate an asymmetric substrate.

In FIG. 4A, an offset layer structure 412 is disposed over the first surface 404 of the central core 400. In this example, the offset layer structure 412 is formed on the first surface 404 as well as on the patterned metallization layer 402. In scenarios in which the asymmetric substrate includes the embedded electronic component 410, the PI tape 320 used in the embedding process is removed and replaced by a dry fill layer 414 over the second surface 408 of the central core 400.

In an aspect, the offset layer structure 412 offset layer structure may include one or more PPG layers, where each PPG layer comprises a fabric that has been impregnated with a resin. In an aspect, such PPG layers may be applied over the first surface 404 of the central core 400 prior to the curing of the resin and subsequently cured during another processing operation of the substrate fabrication process. In an aspect, a single PPG layer may be applied over the first surface 404 to form the offset layer structure 412. In an aspect, multiple PPG layers may be applied over the first surface 404 to form the offset layer structure 412.

In FIG. 4B, vias 416 have been formed in the offset layer structure 412 to couple the patterned metallization layer 402 with upper metallization/dielectric layers that are subsequently formed to provide a completed metallization structure (not shown in FIG. 4B) overlying the first surface 404 of the central core 400. In this example, no further processing takes place at the side of the central core 400 proximate to the second surface 408 and dry fill layer 414 during the formation of the vias 416 in the offset layer structure 412.

In FIG. 4C, a further patterned metallization layer 418 is formed over the offset layer structure 412. In this example, no further processing takes place at the side of the central core 400 proximate to the second surface 408 and dry fill layer 414 has been removed during the formation of the further patterned metallization layer 418.

In FIG. 4D through FIG. 4G, additional patterned metallization layers are added to complete the formation of the metallization structures of the asymmetric substrate. In FIG. 4D, the dry fill layer 414 has been removed. A dielectric layer 420 is disposed over the patterned metallization layer 406 and the second surface 408 of the central core 400. Additionally, a dielectric layer 422 is disposed over the patterned metallization layer 418 and the offset layer structure 412. In an aspect, the processing operations used in the formation of the dielectric layers 420 and 422 may take place concurrently during the same processing step.

In FIG. 4E, vias 424 have been formed in the dielectric layer 422 to couple the patterned metallization layer 418 with a patterned metallization layer 426 that is formed over the dielectric layer 422. Similarly, vias 428 have been formed in the dielectric layer 420 to couple the patterned metallization layer 406 with a patterned metallization layer 430 that is formed over the dielectric layer 420. The formation of the vias 424 and 428 may take place concurrently during the same processing step. Likewise, the formation of the patterned metallization layers 426 and 430 may take place concurrently during the same processing step.

In FIG. 4F, a dielectric layer 432 is disposed over the patterned metallization layer 426 and dielectric layer 422. Additionally, a dielectric layer 434 is disposed over the patterned metallization layer 430 and the dielectric layer 420. In an aspect, the processing operations used in the formation of the dielectric layers 432 and 434 may take place concurrently during the same processing step.

In FIG. 4G, vias 436 have been formed in the dielectric layer 432 to couple the patterned metallization layer 426 with a patterned metallization layer 438 that is formed over the dielectric layer 432. Similarly, vias 440 have been formed in the dielectric layer 434 to couple the patterned metallization layer 430 with a patterned metallization layer 442 that is formed over the dielectric layer 434. The formation of the vias 436, 440 may take place concurrently during the same processing step. Likewise, the formation of the patterned metallization layers 426, 430 may take place concurrently during the same processing step. As such, the metallization structure formed by the patterned metallization layers 402, 418, 426, and 438 is completed concurrently with the metallization structure formed by the patterned metallization layers 406, 430, and 442.

In FIG. 4H, the fabrication of the asymmetric substrate 446 is completed with the formation of patterned solder mask layers. In this example, a patterned solder mask layer 448 formed over the dielectric layer 432 and patterned metallization layer 438. The patterned solder mask layer 448 leaves regions of the patterned metallization layer 438 exposed for use as connection pads 450. Similarly, a patterned solder mask layer 452 is formed over the dielectric layer 434 and patterned metallization layer 442. The patterned solder mask layer 452 leaves regions of the patterned metallization layer 442 exposed for use as connection pads 454. In an aspect, the processing operations used in the formation of the patterned solder mask layers 448 and 452 may take place concurrently during the same processing step.

In FIG. 4I, the asymmetric substrate 446 shown in FIG. 4H has been inverted for subsequent packaging operations. Here, the asymmetric substrate 446 includes an upper metallization structure 458 comprised of three patterned metallization layers 406, 430, and 442. The asymmetric substrate 446 also includes a lower metallization structure 460 comprised of four patterned metallization layers 402, 418, 426, and 438. As such, the asymmetric substrate 446 may be considered a seven-layer substrate with four metallization layers disposed at a first side of the central core and three metallization layers disposed at a second side of the central core.

The arrangement of the connection pads 450, 454 is dependent on the particular end use of the asymmetric substrate 446. In an aspect, the connection pads 454 may be configured for coupling the asymmetric substrate 446 to a die used in a PDN. In an aspect, the connection pads 450 may be configured for coupling the asymmetric substrate 446 to a PCB and/or other electronic components (e.g., dies, ICs, discrete active components, discrete passive components, etc.)

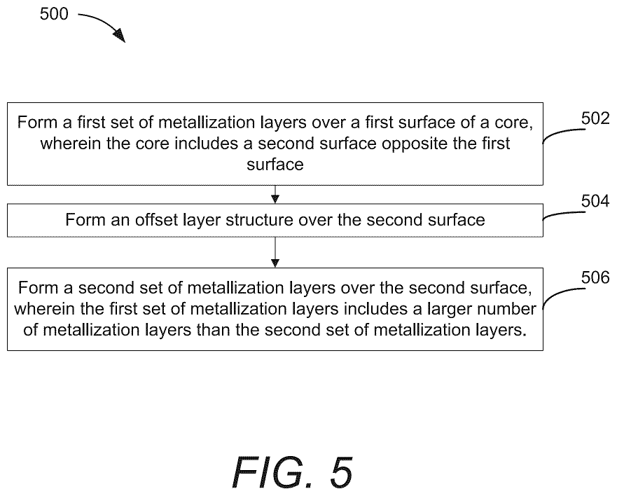

FIG. 5 is a flowchart showing an example method 500 for fabricating a substrate, according to aspects of the disclosure. At operation 502, a first set of metallization layers is formed over a first surface of a core, wherein the core includes a second surface opposite the first surface. At operation 504, an offset layer structure is formed over the second surface. At operation 506, a second set of metallization layers is formed over the second surface, wherein the first set of metallization layers includes a larger number of metallization layers than the second set of metallization layers.

A technical advantage of the method 500 is that it may be used to form an asymmetric substrate having metallization structures with different numbers of metallization layers at opposite sides of a central core.

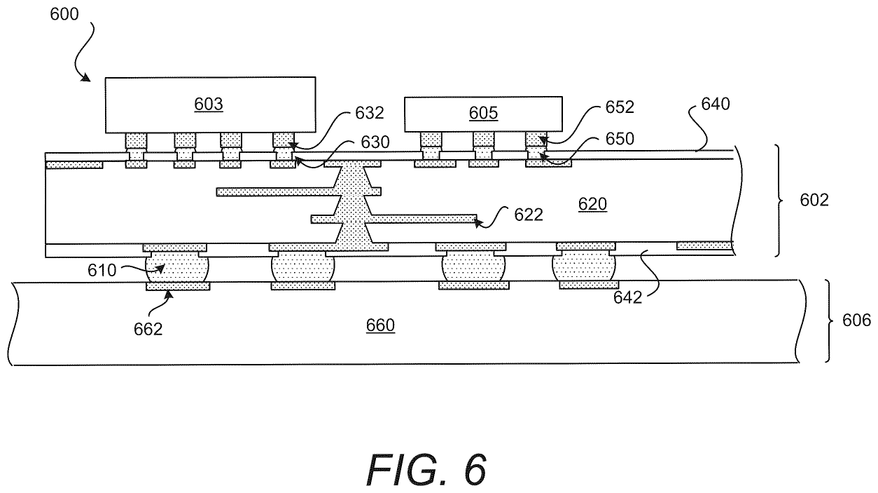

FIG. 6 illustrates a profile view of a package 600 that includes a surface mount asymmetric substrate 602, an integrated device 603, and an integrated passive device 605, according to aspects of the disclosure. The package 600 may be coupled to a printed circuit board (PCB) 606 through a plurality of solder interconnects 610. The PCB 606 may include at least one board dielectric layer 660 and a plurality of board interconnects 662.

The surface mount asymmetric substrate 602 includes at least one dielectric layer 620 (e.g., substrate dielectric layer), a plurality of interconnects 622 (e.g., substrate interconnects), a solder resist layer 640 and a solder resist layer 642. The integrated device 603 may be coupled to the surface mount asymmetric substrate 602 through a plurality of solder interconnects 630. The integrated device 603 may be coupled to the surface mount asymmetric substrate 602 through a plurality of pillar interconnects 632 and the plurality of solder interconnects 630. The integrated passive device 605 may be coupled to the surface mount asymmetric substrate 602 through a plurality of solder interconnects 650. The integrated passive device 605 may be coupled to the surface mount asymmetric substrate 602 through a plurality of pillar interconnects 652 and the plurality of solder interconnects 650.

The package (e.g., 600) may be implemented in a radio frequency (RF) package. The RF package may be a radio frequency front end (RFFE) package. A package (e.g., 600) may be configured to provide Wireless Fidelity (WiFi) communication and/or cellular communication (e.g., 2G, 3G, 4G, 5G). The package (e.g., 600.) may be configured to support Global System for Mobile (GSM) Communications, Universal Mobile Telecommunications System (UMTS), and/or Long-Term Evolution (LTE). The package (e.g., 600) may be configured to transmit and receive signals having different frequencies and/or communication protocols.

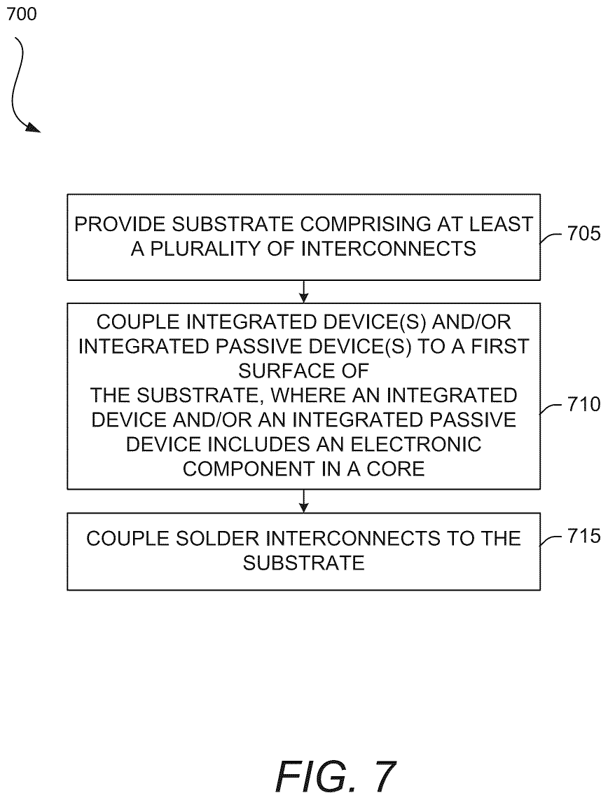

FIG. 7 illustrates an example method 700 for providing or fabricating a package that includes an integrated device comprising an electronic component mounted in a core, according to aspects of the disclosure. In some implementations, the method 700 of FIG. 7 may be used to provide or fabricate the package 600 of FIG. 6 described in the disclosure. However, the method 700 may be used to provide or fabricate any of the packages described in the disclosure.

It should be noted that the method of FIG. 7 may combine one or more processes in order to simplify and/or clarify the method for providing or fabricating a package that includes an integrated device comprising an electronic component mounted in a core, according to aspects of the disclosure. In some implementations, the order of the processes may be changed or modified.

The method provides (at 705) a substrate (e.g., 602). The surface mount asymmetric substrate 602 may be provided by a supplier or fabricated. The surface mount asymmetric substrate 602 includes at least one dielectric layer 620, and a plurality of interconnects 622. The surface mount asymmetric substrate 602 may include an embedded trace substrate (ETS). In some implementations, the at least one dielectric layer 620 may include pre-preg layers.

The method couples (at 710) at least one integrated device (e.g., 603) to the first surface of the substrate (e.g., 602). For example, the integrated device 603 may be coupled to the surface mount asymmetric substrate 602 through the plurality of pillar interconnects 632 and the plurality of solder interconnects 630. The plurality of pillar interconnects 632 may be optional. The plurality of solder interconnects 630 are coupled to the plurality of interconnects 622. A solder reflow process may be used to couple the integrated device 603 to the plurality of interconnects through the plurality of solder interconnects 630.

The method also couples (at 710) at least one integrated passive device (e.g., 605) to the first surface of the substrate (e.g., 602). For example, the integrated passive device 605 may be coupled to the surface mount asymmetric substrate 602 through the plurality of pillar interconnects 652 and the plurality of solder interconnects 650. The plurality of pillar interconnects 652 may be optional. The plurality of solder interconnects 650 are coupled to the plurality of interconnects 622. A solder reflow process may be used to couple the integrated passive device 605 to the plurality of interconnects through the plurality of solder interconnects 650.

The method couples (at 715) a plurality of solder interconnects (e.g., 610) to the second surface of the substrate (e.g., 602). A solder reflow process may be used to couple the plurality of solder interconnects 610 to the substrate.

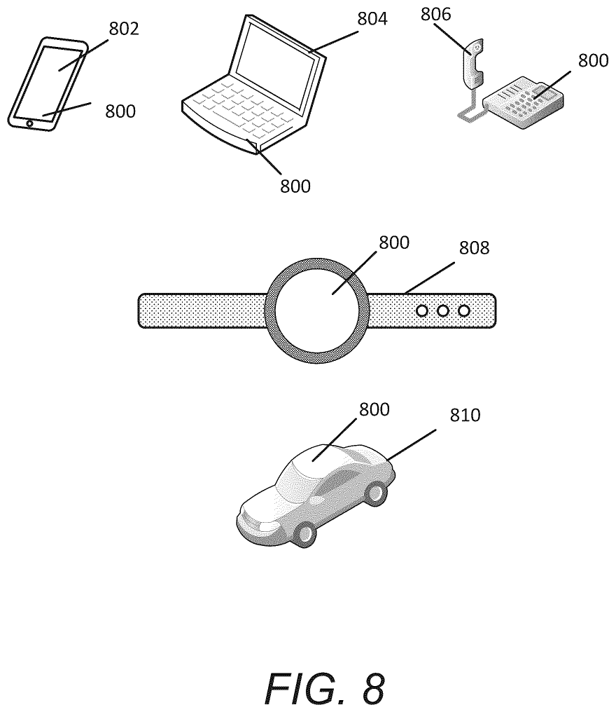

FIG. 8 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 802, a laptop computer device 804, a fixed location terminal device 806, a wearable device 808, or automotive vehicle 810 may include a device 800 as described herein. The device 800 may be, for example, any of the devices and/or integrated circuit (IC) packages described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. A substrate comprising: a core having a first surface and a second surface opposite the first surface; a first set of metallization layers disposed over the first surface; an offset layer structure disposed over the second surface; and a second set of metallization layers disposed over the second surface wherein the second set of metallization layers includes a larger number of metallization layers than the first set of metallization layers.

Aspect 2. The substrate of aspect 1, wherein: the offset layer structure is disposed between metallization layers of the second set of metallization layers.

Aspect 3. The substrate of any of aspects 1 to 2, wherein: the offset layer structure is disposed on the second surface.

Aspect 4. The substrate of any of aspects 1 to 3, wherein: the offset layer structure comprises one or more pre-preg (PPG) layers, each PPG layer comprising a fabric that has been impregnated with a resin.

Aspect 5. The substrate of any of aspects 1 to 4, further comprising: a first set of one or more connection pads disposed at a first outer surface of the substrate over the first set of metallization layers; and a second set of one or more connection pads disposed at a second outer surface of the substrate over the second set of metallization layers, wherein the second set of one or more connection pads are spaced from the second surface of the core at a greater distance than the first set of one or more connection pads are spaced from the first surface of the core.

Aspect 6. The substrate of aspect 5, wherein: the first set of one or more connection pads are configured for connection to one or more die.

Aspect 7. The substrate of any of aspects 5 to 6, wherein: the second set of one or more connection pads are configured for connection to a printed circuit board.

Aspect 8. The substrate of any of aspects 1 to 7, further comprising: an electronic component embedded in the core and electrically coupled to one or more metallization layers of the first set of metallization layers.

Aspect 9. The substrate of aspect 8, wherein: the electronic component comprises at least one deep trench capacitor.

Aspect 10. The substrate of aspect 9, wherein: the one or more metallization layers of the first set of metallization layers form at least a part of a power distribution network.

Aspect 11. An electronic device, comprising: a substrate comprising: a core having a first surface and a second surface opposite the first surface; a first set of metallization layers disposed over the first surface; an offset layer structure disposed over the second surface; and a second set of metallization layers disposed over the second surface, wherein the second set of metallization layers includes a larger number of metallization layers than the first set of metallization layers.

Aspect 12. The electronic device of aspect 11, wherein: the offset layer structure is disposed between metallization layers of the second set of metallization layers.

Aspect 13. The electronic device of any of aspects 11 to 12, wherein: the offset layer structure is disposed on the second surface.

Aspect 14. The electronic device of any of aspects 11 to 13, wherein: the offset layer structure comprises one or more pre-preg (PPG) layers, each PPG layer comprising a fabric that has been impregnated with a resin.

Aspect 15. The electronic device of any of aspects 11 to 14, further comprising: a first set of one or more connection pads disposed at a first outer surface of the substrate over the first set of metallization layers; and a second set of one or more connection pads disposed at a second outer surface of the substrate over the second set of metallization layers, wherein the second set of one or more connection pads are spaced from the second surface of the core at a greater distance than the first set of one or more connection pads are spaced from the first surface of the core.

Aspect 16. The electronic device of aspect 15, wherein: the first set of one or more connection pads are electrically coupled to one or more die.

Aspect 17. The electronic device of any of aspects 15 to 16, wherein: the first set of one or more connection pads are configured for connection to a printed circuit board.

Aspect 18. The electronic device of any of aspects 11 to 17, further comprising: an electronic component embedded in the core and electrically coupled to one or more metallization layers of the first set of metallization layers.

Aspect 19. The electronic device of aspect 18, wherein: the electronic component comprises at least one deep trench capacitor.

Aspect 20. The electronic device of aspect 19, wherein: the one or more metallization layers of the first set of metallization layers form at least a portion of a power distribution network.

Aspect 21. The electronic device of any of aspects 11 to 20, wherein the electronic device comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Aspect 22. A method of fabricating a substrate, comprising: forming a first set of metallization layers over a first surface of a core, wherein the core includes a second surface opposite the first surface; forming an offset layer structure over the second surface; and forming a second set of metallization layers over the second surface, wherein the first set of metallization layers includes a larger number of metallization layers than the second set of metallization layers.

Aspect 23. The method of aspect 22, wherein: the offset layer structure is formed between metallization layers of the second set of metallization layers.

Aspect 24. The method of any of aspects 22 to 23, wherein: the offset layer structure is formed on the second surface.

Aspect 25. The method of any of aspects 22 to 24, wherein: concurrently completing formation of the first set of metallization layers and the second set of metallization layers in a same metallization processing operation.

Aspect 26. The method of any of aspects 22 to 25, wherein: the offset layer structure is formed from one or more pre-preg (PPG) layers, each PPG layer comprising a fabric that has been impregnated with a resin.

Aspect 27. The method of any of aspects 22 to 26, further comprising: forming a first set of one or more connection pads over a first outer surface of the substrate over the first set of metallization layers, wherein the first set of one or more connection pads are configured for connection to one or more die; and forming a second set of one or more connection pads over a second outer surface of the substrate over the second set of metallization layers, wherein the second set of one or more connection pads are spaced from the second surface of the core at a greater distance than the first set of one or more connection pads are spaced from the first surface of the core.

Aspect 28. The method of aspect 27, wherein: the second set of one or more connection pads are configured for connection to a printed circuit board.

Aspect 29. The method of any of aspects 22 to 28, further comprising: embedding an electronic component in the core; and electrically coupling the electronic component with one or more metallization layers of the first set of metallization layers.

Aspect 30. The method of aspect 29, wherein: the electronic component comprises at least one deep trench capacitor.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A substrate comprising:
a core having a first surface and a second surface opposite the first surface;
a first set of metallization layers disposed over the first surface;
an offset layer structure disposed over the second surface; and
a second set of metallization layers disposed over the second surface wherein the second set of metallization layers includes a larger number of metallization layers than the first set of metallization layers.

2. The substrate of claim 1, wherein:
the offset layer structure is disposed between metallization layers of the second set of metallization layers.

3. The substrate of claim 1, wherein:
the offset layer structure comprises one or more pre-preg (PPG) layers, each PPG layer comprising a fabric that has been impregnated with a resin.

4. The substrate of claim 1, further comprising:
a first set of one or more connection pads disposed at a first outer surface of the substrate over the first set of metallization layers; and
a second set of one or more connection pads disposed at a second outer surface of the substrate over the second set of metallization layers, wherein the second set of one or more connection pads are spaced from the second surface of the core at a greater distance than the first set of one or more connection pads are spaced from the first surface of the core.

5. The substrate of claim 1, further comprising:
an electronic component embedded in the core and electrically coupled to one or more metallization layers of the first set of metallization layers.

6. An electronic device, comprising:
a substrate comprising:
a core having a first surface and a second surface opposite the first surface;
a first set of metallization layers disposed over the first surface;
an offset layer structure disposed over the second surface; and
a second set of metallization layers disposed over the second surface,
wherein the second set of metallization layers includes a larger number of metallization layers than the first set of metallization layers.

7. The electronic device of claim 6, wherein:
the offset layer structure is disposed between metallization layers of the second set of metallization layers.

8. The electronic device of claim 6, wherein:
the offset layer structure comprises one or more pre-preg (PPG) layers, each PPG layer comprising a fabric that has been impregnated with a resin.

9. The electronic device of claim 6, further comprising:
a first set of one or more connection pads disposed at a first outer surface of the substrate over the first set of metallization layers; and
a second set of one or more connection pads disposed at a second outer surface of the substrate over the second set of metallization layers, wherein the second set of one or more connection pads are spaced from the second surface of the core at a greater distance than the first set of one or more connection pads are spaced from the first surface of the core.

10. The electronic device of claim 6, further comprising:
an electronic component embedded in the core and electrically coupled to one or more metallization layers of the first set of metallization layers.

11. The electronic device of claim 10, wherein:
the electronic component comprises at least one deep trench capacitor.

12. The electronic device of claim 6, wherein the electronic device comprises at least one of:
a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

13. A method of fabricating a substrate, comprising:
forming a first set of metallization layers over a first surface of a core, wherein the core includes a second surface opposite the first surface;
forming an offset layer structure over the second surface; and
forming a second set of metallization layers over the second surface, wherein the first set of metallization layers includes a larger number of metallization layers than the second set of metallization layers.

14. The method of claim 13, wherein:
the offset layer structure is formed between metallization layers of the second set of metallization layers.

15. The method of claim 13, wherein:
the offset layer structure is formed on the second surface.

16. The method of claim 13, wherein:
concurrently completing formation of the first set of metallization layers and the second set of metallization layers in a same metallization processing operation.

17. The method of claim 13, wherein:
the offset layer structure is formed from one or more pre-preg (PPG) layers, each PPG layer comprising a fabric that has been impregnated with a resin.

18. The method of claim 13, further comprising:
forming a first set of one or more connection pads over a first outer surface of the substrate over the first set of metallization layers, wherein the first set of one or more connection pads are configured for connection to one or more die; and
forming a second set of one or more connection pads over a second outer surface of the substrate over the second set of metallization layers, wherein the second set of one or more connection pads are spaced from the second surface of the core at a greater distance than the first set of one or more connection pads are spaced from the first surface of the core.

19. The method of claim 13, further comprising:
embedding an electronic component in the core; and
electrically coupling the electronic component with one or more metallization layers of the first set of metallization layers.

20. The method of claim 19, wherein:
the electronic component comprises at least one deep trench capacitor.
